(19) United States
(12) Patent Application Publication
(10) Pub. No.: US 2025/0334649 A1
(43) Pub. Date: Oct. 30, 2025

(54) INSPECTION DEVICE FOR DISPLAY DEVICE AND ELECTRONIC DEVICE INCLUDING THE DISPLAY DEVICE AND INSPECTION SYSTEM INCLUDING THE SAME

(71) Applicant: Samsung Display Co., LTD., Yongin-si (KR)

(72) Inventors: Byung Chul SHIN, Yongin-si (KR); Hyun Seop SONG, Yongin-si (KR)

(21) Appl. No.: 18/968,743

(22) Filed: Dec. 4, 2024

(30) Foreign Application Priority Data
Apr. 30, 2024 (KR) 10-2024-0057521

(51) Int. Cl. G01R 31/54; H10K 59/95; H10K 71/70

(52) U.S. Cl. CPC G01R 31/54; H10K 59/95; H10K 71/70

(57) ABSTRACT

An inspection system includes: a display device including: a panel cover on a back surface of a display panel; a printed circuit board on a back surface of the panel cover; and a protective member on a front surface of the printed circuit board; and an inspection device configured to determine conductivity between the panel cover, the printed circuit board, and the protective member based on a resistance measured from a first area of the protective member, a second area of the panel cover, and a third area of the printed circuit board.

### CROSS-REFERENCE TO RELATED APPLICATION

The present application claims priority to and the benefit of Korean Patent Application No. 10-2024-0057521, filed on Apr. 30, 2024, in the Korean Intellectual Property Office, the entire disclosure of which is incorporated herein by reference.

### BACKGROUND

### 1. Field

Aspects of some embodiments of the present disclosure relate to an inspection device for a display device and an electronic device including the display device and an inspection system including the same.

### 2. Description of the Related Art

As technology develops, display devices may include electronic components that perform various functions. The electronic component may include a main printed circuit board (PCB) of the display device, and the electronic component may be connected to the main printed circuit board through a connector to receive a power source or transmit and receive signals.

The display device may include a display panel cover to protect a display panel included in the display device. In this case, in a process of manufacturing the display device, the main printed circuit board may be located on the display panel cover. In addition, a protective member for protecting components of the main printed circuit board may be located on the main printed circuit board. If conductive areas of the display panel cover, the protective member, and the main printed circuit board are not conductive, driving reliability of the display device may decrease.

The above information disclosed in this Background section is only for enhancement of understanding of the background and therefore the information discussed in this Background section does not necessarily constitute prior art.

### SUMMARY

Aspects of some embodiments of the present disclosure include an inspection device that inspects conductivity in a state in which a display panel cover, a protective member, and a main printed circuit board are located, and an inspection system including the same.

Aspects of some embodiments of the present disclosure include a display device in which driving reliability can be relatively improved by inspecting conductivity in conductive areas of a display panel cover, a protective member, and a main printed circuit board.

According to some embodiments of the present disclosure, an inspection system includes: a display device including a panel cover on a back surface of a display panel, a printed circuit board on a back surface of the panel cover, and a protective member on a front surface of the printed circuit board; and an inspection device determining conductivity between the panel cover, the printed circuit board, and the protective member based on a resistance measured from a first area of the protective member, a second area of the panel cover, and a third area of the printed circuit board.

According to some embodiments, the inspection device may include a first pin in contact with the first area, a second pin in contact with the second area, and a third pin in contact with the third area, and simultaneously (or concurrently) contact the first to third pins to the first to third areas and determine the conductivity based on a measured resistance.

According to some embodiments, when the first to third pins are simultaneously (or concurrently) contacted to the first to third areas and the measured resistance is ‘0’, the inspection device may determine that conductivity exists between the panel cover, the printed circuit board, and the protection member.

According to some embodiments, the protective member may include a conductive layer and a non-conductive layer, and the first area may be an area where a portion of the non-conductive layer is removed and the conductive layer is exposed.

According to some embodiments, the conductive layer may be on the front surface of the printed circuit board, and the non-conductive layer may be on the conductive layer.

According to some embodiments, the second area may be an area where a layer including a conductive material of the panel cover is exposed.

According to some embodiments, the second area may be an area where a portion of a release paper protecting the panel cover is removed and the layer including the conductive material is exposed.

According to some embodiments, the printed circuit board may include a ground area, and the third area may be an area where the protective member is removed and the ground area of the printed circuit board is exposed.

According to some embodiments, the ground area may have a ground potential.

According to some embodiments, the inspection device may include an upper cover in contact with the first to third pins.

According to some embodiments, the inspection device may include a first wire connecting the first and second pins, a second wire connecting the second and third pins, and a third wire connecting the first and third pins.

According to some embodiments, the display panel may further include a bending area extending from the display panel, and the printed circuit board is positioned on the back surface of the panel cover as the bending area is bent.

According to some embodiments of the present disclosure, an inspection device includes: a first pin in contact with a first area of a protective member of a display device; a second pin in contact with a second area of a panel cover of the display device; and a third pin in contact with a third area of a printed circuit board of the display device, and conductivity between the panel cover, the printed circuit board, and the protective member may be determined based on a resistance measured from the first to third areas.

According to some embodiments, the inspection device may simultaneously (or concurrently) contact the first to third pins to the first to third areas and determine the conductivity based on a measured resistance.

According to some embodiments, when the first to third pins are simultaneously (or concurrently) contacted to the first to third areas and the measured resistance is ‘0’, the inspection device may determine that conductivity exists between the panel cover, the printed circuit board, and the protection member.

According to some embodiments, the protective member may include a conductive layer and a non-conductive layer, and the first area may be an area where a portion of the non-conductive layer is removed and the conductive layer is exposed.

According to some embodiments, the second area may be an area where a layer including a conductive material of the panel cover is exposed.

According to some embodiments, the third area may be an area where the protective member is removed and a ground area of the printed circuit board is exposed.

According to some embodiments, the inspection device may further include an upper cover in contact with the first to third pins.

According to some embodiments, the panel cover may be on a back surface of the display panel, the printed circuit board may be on a back surface of the panel cover, and the protective member may be on a front surface of the printed circuit board.

Aspects of some embodiments of the present disclosure include an electronic device including a processor to provide input image data, and a display device to display an image based on the input image data, the display device including a panel cover on a back surface of a display panel, a printed circuit board on a back surface of the panel cover, and a protective member on a front surface of the printed circuit board and wherein conductivity between the panel cover, the printed circuit board, and the protective member is determined based on a resistance measured from a first area of the protective member, a second area of the panel cover, and a third area of the printed circuit board.

According to some embodiments, the protective member includes a conductive layer and a non-conductive layer, and wherein the first area is an area where a portion of the non-conductive layer is removed and the conductive layer is exposed.

According to some embodiments, the display panel further includes a bending area extending from the display panel, and wherein the printed circuit board is positioned on a back surface of the panel cover as the bending area is bent.

### BRIEF DESCRIPTION OF THE DRAWINGS

The accompanying drawings, which are included to provide a further understanding of the inventive concepts, and are incorporated in and constitute a part of this specification, illustrate aspects of some embodiments of the present disclosure, and, together with the description, serve to explain characteristics of embodiments according to the present disclosure.

FIG. 1 is a perspective view of a display device according to some embodiments of the present invention.

FIG. 2 is an exploded perspective view of the display device of FIG. 1.

FIG. 3 is a plan view illustrating a panel cover and a printed circuit board after the bending area of FIG. 2 is bent.

FIG. 4 is a plan view illustrating a panel cover, a printed circuit board, and a protective member according to some embodiments of the present invention.

FIG. 5 is a plan view illustrating embodiments in which the protective member of FIG. 4 is located on the panel cover.

FIG. 6 is a cross-sectional view taken along the line I-I′ of FIG. 5.

FIG. 7 is a diagram illustrating pins for a conductivity inspection.

FIG. 8 is a diagram illustrating an inspection device including the pins of FIG. 7.

FIG. 9 is a block diagram illustrating an electronic device in accordance with embodiments of the present disclosure.

FIG. 10 is a schematic diagram illustrating an example where the electronic device of FIG. 9 is a tablet computer.

### DETAILED DESCRIPTION

Hereinafter, aspects of some embodiments of the present invention will be described in more detail with reference to the accompanying drawings. It should be noted that in the following description, only the parts necessary to understand the operation according to the present invention will be described, and descriptions of other parts will be omitted in order to not obscure the gist of the present invention. In addition, embodiments according to the present invention are not limited to the embodiments described herein and may be embodied in other forms. The embodiments described herein are provided merely to explain in detail enough to enable those skilled in the art to easily implement the technical idea of the present invention.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the present invention. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing the relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in the present disclosure, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

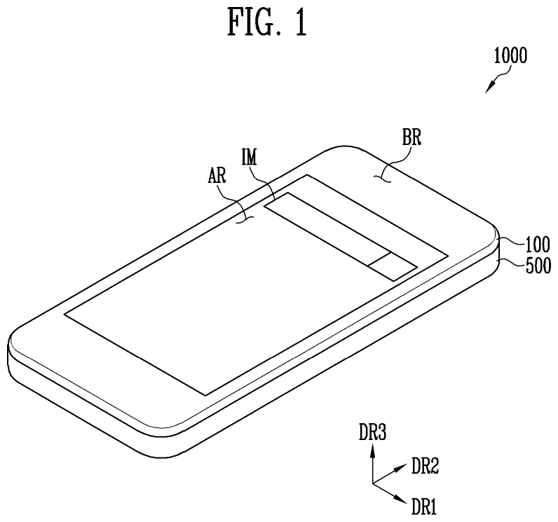

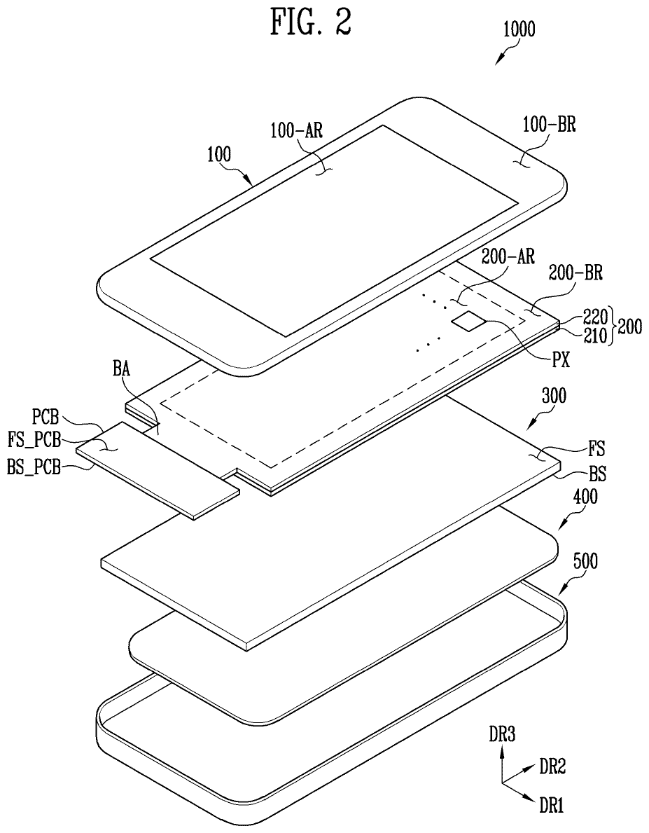

FIG. 1 is a perspective view of a display device according to some embodiments of the present invention. FIG. 2 is an exploded perspective view of the display device of FIG. 1.

Referring to FIG. 1, a display device 1000 may include a plurality of distinct areas on a display surface. For example, the display device 1000 may include a display area AR and a non-display area BR adjacent to the display area AR. The display area AR may be an area where an image IM is displayed.

In an embodiment, as illustrated in FIG. 1, an electronic device including the display device 1000 may be implemented as a smartphone.

The display area AR may have a square shape. The non-display area BR may be arranged to surround (e.g., in a periphery or outside a footprint of) the display area AR. However, embodiments according to the present invention are not limited thereto.

Referring to FIG. 2, the display device 1000 may include a window member 100, a display panel 200, a panel cover 300, a bracket 400, and a rear case 500.

The window member 100 may be located on top of the display panel 200. Accordingly, a display surface (for example, an upper surface in a third direction DR3) of the display panel 200 can be protected. In addition, the window member 100 may be combined with the display panel 200. For example, the window member 100 may be combined to cover the display surface of the display panel 200.

The window member 100 may include a display area 100-AR that transmits the image IM provided by the display panel 200 and a non-display area 100-BR adjacent to the display area 100-AR.

The window member 100 may include an optically transparent insulating material. For example, a window WIN may include glass or plastic. In addition, the window WIN may have a multi-layer structure or a single-layer structure. For example, the window WIN may include a plurality of plastic films bonded with an adhesive, or may include a glass substrate and a plastic film bonded with an adhesive.

The display panel 200 may include a substrate 210, an encapsulation layer 220, pixels PX, a bending area BA, and a printed circuit board PCB.

The display panel 200 may have the display surface that displays the image IM and a back surface that faces the display surface. The display surface may correspond to an upper surface of the encapsulation layer 220. The back surface may correspond to a lower surface of the substrate 210.

The display panel 200 may include a display area 200-AR and a non-display area 200-BR. The display area 200-AR may be an area that displays the image IM, and may correspond to the display area 100-AR of the window member 100. The non-display area 200-BR may be adjacent to the display area 200-AR and may correspond to the non-display area 100-BR of the window member 100.

The substrate 210 may be a rigid substrate made of glass. In addition, the substrate 210 may be a flexible substrate capable of bending, folding, rolling, or the like. In this case, the substrate 210 may include an insulating material such as a polymer resin such as polyimide.

According to some embodiments, the substrate 210 may include a silicon wafer substrate formed through a semiconductor process. The substrate 210 may include a semiconductor material suitable for forming circuit elements. For example, the semiconductor material may include silicon, germanium, and/or silicon-germanium. The substrate 210 may be provided from a bulk wafer, an epitaxial layer, a silicon on insulator (SOI) layer, a semiconductor on insulator (SeOI) layer, or the like.

The encapsulation layer 220 may be located on the substrate 210. When the encapsulation layer 220 is in the form of an encapsulation film, the encapsulation layer 220 may include an inorganic film and/or an organic film. The encapsulation layer 220 may protect the pixels PX from moisture and oxygen. In addition, the encapsulation layer 220 may protect the pixels PX from foreign substances such as dust particles.

Among a plurality of pixels PX, pixels PX arranged along a first direction DR1 may form a pixel row and pixels PX arranged along a second direction DR2 may form a pixel column. Each of the pixels PX may include a plurality of sub-pixels. For example, each of the plurality of pixels PX may include a first pixel configured to emit red light, a second pixel configured to emit green light, and a third pixel configured to emit blue light.

Each of the plurality of pixels PX may include a light emitting element and a pixel circuit configured to drive the light emitting element. According to some embodiments, the light emitting element may be provided in various forms. For example, the light emitting element may be an inorganic light emitting element including an inorganic material. According to some embodiments, the light emitting element may be an organic light emitting diode. However, embodiments according to the present invention are not limited thereto. For example, the light emitting element may be a quantum dot light emitting diode.

The bending area BA may be a portion where the display panel 200 is folded. The bending area BA may be bent onto the back surface BS of the panel cover 300. For example, the bending area BA may be bent in a direction opposite to the third direction DR3 so that the printed circuit board PCB overlaps the panel cover 300.

The bending area BA may include a flexible printed circuit board (FPCB). Accordingly, the bending area BA may electrically connect the display panel 200 and the printed circuit board PCB. For example, the display panel 200 and the printed circuit board PCB may transmit and receive drive signals through the flexible printed circuit board. For example, the driving signals may be various signals for driving the display device 1000, such as a driving voltage, a gate signal, a data signal, and the like. However, embodiments according to the present invention are not limited thereto.

The printed circuit board PCB may output a signal to the display panel 200 or receive a signal from the display panel 200 through the bending area BA. According to some embodiments, the printed circuit board PCB may include a connector for receiving signals from outside. Accordingly, the printed circuit board PCB may supply at least some of the signals received from the outside to the display panel 200.

As the bending area BA is bent, the printed circuit board PCB may be positioned on the back surface BS of the panel cover 300. For example, as the bending area BA is bent, the back surface BS_PCB of the printed circuit board PCB may be in contact with the back surface BS of the panel cover 300.

The panel cover 300 may be located on the back surface of the display panel 200. For example, the panel cover 300 may be arranged so that the front surface FS of the panel cover 300 faces the back surface of the display panel 200. In a combined state, the panel cover 300 may be located between the display panel 200 and the printed circuit board PCB.

The panel cover 300 may be configured to protect the display panel 200. For example, the panel cover 300 may include a light blocking layer, a heat dissipation layer, and a shielding layer.

The light blocking layer may block light incident on the display panel 200. For example, the light blocking layer may be located on the back surface of the display panel 200 to block light incident on the display panel 200 in the third direction DR3 and/or in a direction opposite to the third direction DR3. According to some embodiments, the light blocking layer may include a resin layer including polyethylene terephthalate (PET) or the like, and a light blocking layer positioned on a back surface of the resin layer. The light blocking layer may be a black tape or a coating layer made of a light blocking material.

The heat dissipation layer may be positioned on a back surface of the light blocking layer. For example, the heat dissipation layer may be located between the light blocking layer and the shielding layer. The heat dissipation layer may include a material with high thermal conductivity. Accordingly, heat generated from the display panel 200 can be effectively dissipated. For example, the heat dissipation layer may absorb heat generated from the display panel 200 and dissipate the absorbed heat through high thermal conductivity. According to some embodiments, the heat dissipation layer may include graphite. The graphite may have a plate-shaped structure in which carbon atoms are connected in a horizontal direction.

The shielding layer may be located on a back surface of the heat dissipation layer. For example, the shielding layer may be a layer positioned at the bottom of the panel cover 300. In other words, the shielding layer may be a layer in contact with the back surface BS_PCB of the printed circuit board PCB. However, embodiments according to the present invention are not limited thereto. The shielding layer may be located on the back surface BS_PCB of the printed circuit board PCB to reduce the intensity of electromagnetic waves generated from the printed circuit board PCB.

According to some embodiments, the shielding layer may include at least one of various metal materials such as aluminum (Al), copper (Cu), silver (Ag), magnesium (Mg), platinum (Pt), palladium (Pd), gold (Au), nickel (Ni), neodymium (Nd), iridium (Ir), chromium (Cr), titanium (Ti), molybdenum (Mo), and an alloy thereof. In addition, the shielding layer may be formed as a multi-layer or single-layer structure including the above materials. In addition, the shielding layer may include at least one of conductive oxides such as indium tin oxide (ITO), indium zinc oxide (IZO), zinc oxide (ZnOx), and indium gallium zinc oxide (IGZO). The zinc oxide (ZnOx) may be zinc oxide (ZnO) and/or zinc peroxide (ZnO₂).

According to some embodiments, the panel cover 300 may include a release paper located on a back surface of the shielding layer. The release paper may be a film that protects the panel cover 300. That is, in embodiments in which the panel cover 300 includes a release paper, the release paper may be a layer positioned at the bottom of the panel cover 300. In other words, the release paper may be a layer in contact with the back surface BS_PCB of the printed circuit board PCB.

The bracket 400 may support the display panel 200 and the panel cover 300. One side of the bracket 400 may be attached to the panel cover 300, and the other side of the bracket 400 may provide a space where electronic components can be mounted.

The rear case 500 may accommodate the display panel 200 and the panel cover 300 and may be combined with the window member 100. The rear case 500 may include plastic or metal.

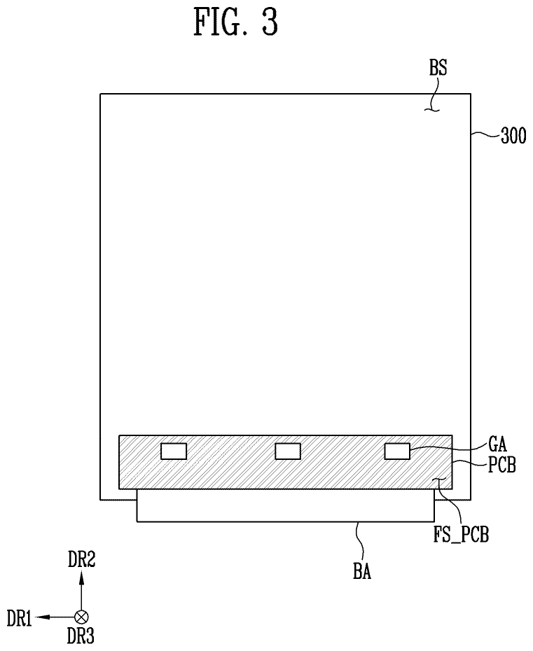

FIG. 3 is a plan view illustrating a panel cover and a printed circuit board after the bending area of FIG. 2 is bent.

Referring to FIG. 3, after the bending area BA is bent, the back surface BS of the panel cover 300 and the back surface BS_PCB of the printed circuit board PCB are shown. As the bending area BA is bent in a direction opposite to the third direction DR3, the printed circuit board PCB may be positioned on the back surface BS of the panel cover 300. According to some embodiments, the back surface of the printed circuit board PCB may be attached to the panel cover 300, and the front surface FS_PCB of the printed circuit board PCB may be exposed in the third direction DR3. The printed circuit board PCB may include a plurality of ground areas GA.

The plurality of ground areas GA may be areas having a ground potential. For example, the ground areas GA may be located on the front surface FS_PCB of the printed circuit board PCB. The ground areas GA may be arranged in the first direction DR1. However, embodiments according to the present invention are not limited thereto. The ground areas GA may be located on the back surface of the printed circuit board PCB, and the ground areas GA may be arranged in the second direction DR2 and the third direction DR3.

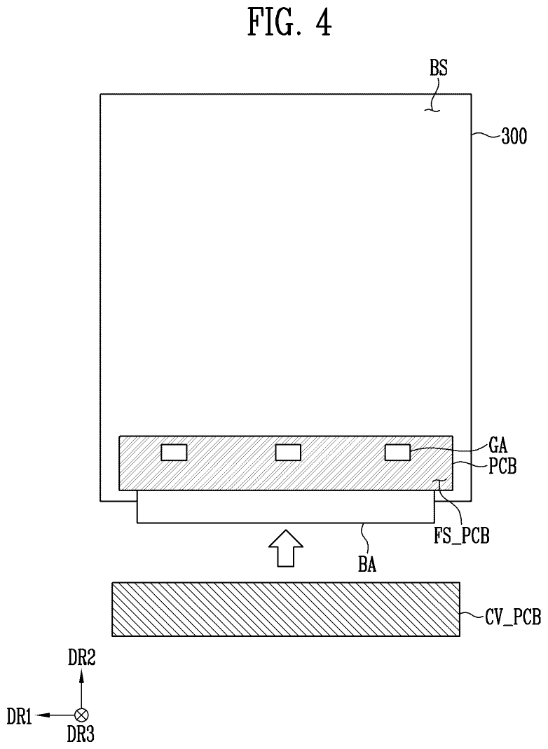

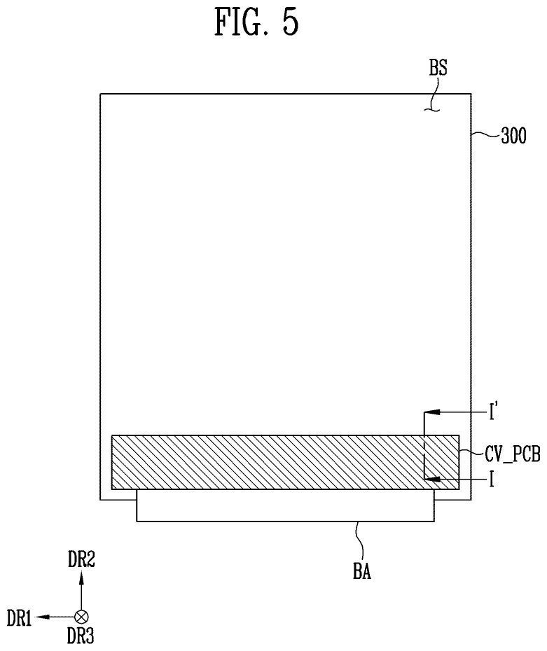

FIG. 4 is a plan view illustrating a panel cover, a printed circuit board, and a protective member according to some embodiments of the present invention. FIG. 5 is a plan view illustrating embodiments in which the protective member of FIG. 4 is located on the panel cover.

Referring to FIGS. 4 and 5, the protective member CV_PCB may be located on the printed circuit board PCB. For example, the protective member CV_PCB may contact at least a portion of the front surface FS_PCB of the printed circuit board PCB and may overlap the printed circuit board PCB.

In a plan view, the protective member CV_PCB may have an area equal to or larger than an area of the printed circuit board PCB. For example, the protective member CV_PCB may have an area relatively larger than the area of the printed circuit board PCB on a plane defined by the first direction DR1 and the second direction DR2. The protective member CV_PCB may cover at least a portion of the printed

circuit board PCB. The protective member CV_PCB may be arranged to overlap the printed circuit board PCB.

The protective member CV_PCB may include a conductive layer and a non-conductive layer. For example, the conductive layer may be located on the front surface FS_PCB of the printed circuit board PCB, and the non-conductive layer may be located on the conductive layer. According to some embodiments, the protective member CV_PCB may include a conductive area in contact with the front surface FS_PCB of the printed circuit board PCB and a non-conductive layer located on the conductive area.

That is, as the non-conductive layer of the protective member CV_PCB is exposed to the outside, the protective member CV_PCB may not expose the printed circuit board PCB to the outside. Accordingly, wires and components located on the printed circuit board PCB can be protected from the outside.

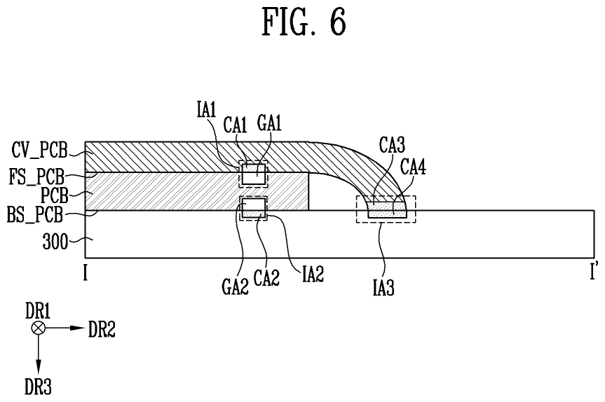

FIG. 6 is a cross-sectional view taken along the line I-I′ of FIG. 5.

Referring to FIG. 6, the panel cover 300 located on the back surface BS_PCB of the printed circuit board PCB and the protective member CV_PCB located on the front surface FS_PCB of the printed circuit board PCB are shown.

For convenience of illustration, wires and components located on the printed circuit board PCB are omitted, and the conductive layer and the non-conductive layer of the protective member CV_PCB are also omitted.

The printed circuit board PCB may include a first ground area GA1 and a second ground area GA2. The first ground area GA1 and the second ground area GA2 may be some of the ground areas GA shown in FIGS. 3 and 4.

The first ground area GA1 may be located on the front surface FS_PCB of the printed circuit board PCB. The second ground area GA2 may be located on the back surface BS_PCB of the printed circuit board PCB.

The protective member CV_PCB may include a first conductive area CA1 and a third conductive area CA3. The first conductive area CA1 and the third conductive area CA3 may be areas including a conductive material. According to some embodiments, the first conductive area CA1 and the third conductive area CA3 may be included in the conductive layer of the protective member CV_PCB.

The panel cover 300 may include a second conductive area CA2 and a fourth conductive area CA4. The second conductive area CA2 and the fourth conductive area CA4 may be areas including a conductive material.

The first ground area GA1 and the first conductive area CA1 may overlap each other. The second ground area GA2 and the second conductive area CA2 may overlap each other. The third conductive area CA3 and the fourth conductive area CA4 may overlap each other.

Accordingly, conductive current of the panel cover 300, the printed circuit board PCB, and the protective member CV_PCB may be conducted to the first and second ground areas GA1 and GA2. Therefore, electromagnetic waves generated from the printed circuit board PCB can be reliably shielded. That is, it may be possible to prevent or reduce the risk of electrostatic discharge (ESD) occurring because electromagnetic waves generated from the printed circuit board PCB are not reliably shielded.

After the panel cover 300, the printed circuit board PCB, and the protective member CV_PCB are arranged, a conductivity inspection may be performed to confirm conductivity between the panel cover 300, the printed circuit board PCB, and the protective member CV_PCB.

The conductivity inspection may be performed to confirm whether the first ground area GA1 and the first conductive area CA1 overlap in a first inspection area IA1, whether the second ground area GA2 and the second conductive area CA2 overlap in a second inspection area IA2, and whether the third conductive area CA3 and the fourth conductive area CA4 overlap in a third inspection area IA3.

If there is overlap in at least one of the first inspection area IA1, the second inspection area IA2, and the third inspection area IA3, it can be determined that there is conductivity between the panel cover 300, the printed circuit board PCB, and the protective member CV_PCB.

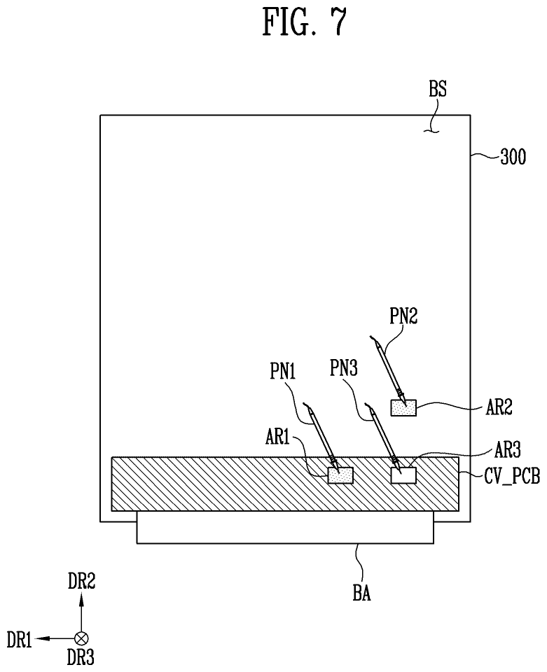

That is, when the first ground area GA1 and the first conductive area CA1 overlap in the first inspection area IA1, the second ground area GA2 and the second conductive area CA2 overlap in the second inspection area IA2, or the third conductive area CA3 and the fourth conductive area CA4 overlap in the third inspection area IA3, it can be determined that there is conductivity between the panel cover 300, the printed circuit board PCB, and the protective member CV_PCB. A more detailed description of this will be described later with reference to FIG. 7.

For convenience of description, the first and second ground areas GA1 and GA2 and the first to fourth conductive areas CA1 to CA4 are only shown as partial areas, and embodiments according to the present disclosure are not limited thereto. According to embodiments, the first and second ground areas GA1 and GA2 and the first to fourth conductive areas CA1 to CA4 may be composed of one layer.

In addition, positions of the first and second ground areas GA1 and GA2 and the first to fourth conductive areas CA1 to CA4 are not limited to the positions shown in FIG. 6. According to embodiments, the first and second ground areas GA1 and GA2 and the first to fourth conductive areas CA1 to CA4 may be arranged in positions different from those shown in FIG. 6.

FIG. 7 is a diagram illustrating pins for a conductivity inspection.

Referring to FIG. 7, a first area AR1, a second area AR2, and a third area AR3 for performing a conductivity inspection are shown. FIG. 7 shows embodiments of the first area AR1, the second area AR2, and the third area AR3 in a state in which the printed circuit board PCB is located on the back surface BS of the panel cover 300 described with reference to FIGS. 4 and 5, and the protective member CV_PCB is located on the front surface FS_PCB of the printed circuit board PCB.

The first area AR1 may be a conductive area of the protective member CV_PCB. The first area AR1 may be one of the first conductive area CA1 and the third conductive area CA3 shown in FIG. 6. For example, the first area AR1 may be an area where the conductive layer of the protective member CV_PCB is exposed by removing a portion of the non-conductive layer of the protective member CV_PCB.

The second area AR2 may be a conductive area of the panel cover 300. The second area AR2 may be one of the second conductive area CA2 and the fourth conductive area CA4 shown in FIG. 6. For example, the second area AR2 may be an area where a layer including a conductive material of the panel cover 300 is exposed by removing a portion of the release paper of the panel cover 300.

The third area AR3 may be a ground area of the a printed circuit board PCB. The third area AR3 may be one of the first ground area GA1 and the second ground area GA2 shown in FIG. 6. For example, the third area AR3 may be an area where the ground area GA of the printed circuit board PCB of FIG. 4 is exposed by removing the protective member CV_PCB.

An inspection device that performs the conductivity inspection may include a first pin PN1 in contact with the first area AR1, a second pin PN2 in contact with the second area AR2, and a third pin PN3 in contact with the third area AR3.

According to some embodiments, the inspection device may be a device that measures resistance. For example, the inspection device may be a multimeter, and the first to third pins PN1 to PN3 may be probe pins of the multimeter.

The inspection device may contact the first to third pins PN1 to PN3 to the first to third areas AR1 to AR3, respectively, and perform a conductivity inspection based on the measured resistance.

According to some embodiments, when the first to third pins PN1 to PN3 are simultaneously (or concurrently) contacted to the first to third areas AR1 to AR3 and the measured resistance is ‘00’, the inspection device may determine that there is conductivity between the panel cover 300, the printed circuit board PCB, and the protective member CV_PCB.

That is, when the first to third pins PN1 to PN3 are simultaneously (or concurrently) contacted to the first to third areas AR1 to AR3 and the measured resistance is ‘00’, the inspection device may determine that conductivity exists in at least one of the first inspection area IA1, the second inspection area IA2, and the third inspection area IA3 shown in FIG. 6.

When the first to third pins PN1 to PN3 are simultaneously (or concurrently) contacted to the first to third areas AR1 to AR3 and the measured resistance is not ‘00’, the inspection device may determine that there is no conductivity between the panel cover 300, the printed circuit board PCB, and the protective member CV_PCB.

That is, when the first to third pins PN1 to PN3 are simultaneously (or concurrently) contacted to the first to third areas AR1 to AR3 and the measured resistance is not ‘00’, the inspection device may determine that there is no conductivity in all of the first inspection area IA1, the second inspection area IA2, and the third inspection area IA3.

The resistance measured from the first area AR1 and the third area AR3 may be the resistance measured from the first inspection area IA1. The resistance measured from the second area AR2 and the third area AR3 may be the resistance measured from the second inspection area IA2. The resistance measured from the first area AR1 and the second area AR2 may be the resistance measured from the third inspection area IA3.

Positions of the first to third areas AR1 to AR3 are not limited to the positions shown in FIG. 7. According to embodiments, the first to third areas AR1 to AR3 may be located in positions different from those shown in FIG. 7.

According to some embodiments, the conductivity inspection may be performed in a state in which the printed circuit board PCB is located on the back surface BS of the panel cover 300, and the protective member CV_PCB is located on the front surface FS_PCB of the printed circuit board PCB.

In other embodiments, after the printed circuit board PCB is located on the back surface BS of the panel cover 300 and the protective member CV_PCB is located on the front surface FS_PCB of the printed circuit board PCB, in the step of inspecting the operation of the printed circuit board PCB, the conductivity inspection may be performed. In addition, in the step of inspecting the state in which the printed circuit board PCB is located on the back surface BS of the panel cover 300 and the protective member CV_PCB is located on the front surface FS_PCB of the printed circuit board PCB, the conductivity inspection may be performed. That is, as the conductivity inspection is performed together with other inspections, the inspection time can be reduced.

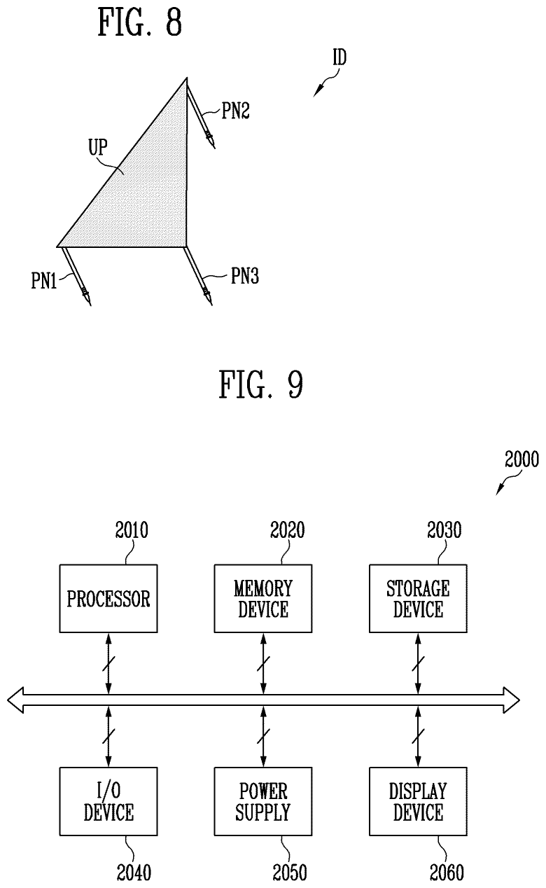

FIG. 8 is a diagram illustrating an inspection device including the pins of FIG. 7.

Referring to FIG. 8, an inspection device ID including first to third pins PN1 to PN3 and an upper cover UP is shown. Because the first to third pins PN1 to PN3 of

FIG. 8 may be similar to the first to third pins PN1 to PN3 of FIG. 7, some detailed descriptions may be omitted.

The inspection device ID may include the upper cover UP in contact with the first to third pins PN1 to PN3. Accordingly, the inspection device ID may simultaneously (or concurrently) contact the first to third pins PN1 to PN3 to the first to third areas AR1 to AR3 and measure the resistance.

However, embodiments according to the present disclosure are not limited thereto. The inspection device ID may further include wires or cables connecting the first to third pins PN1 to PN3. According to some embodiments, the inspection device ID may include a first wire connecting the first and second pins PN1 and PN2, a second wire connecting the second and third pins PN2 and PN3, and a third wire connecting the first and third pins PN1 and PN3.

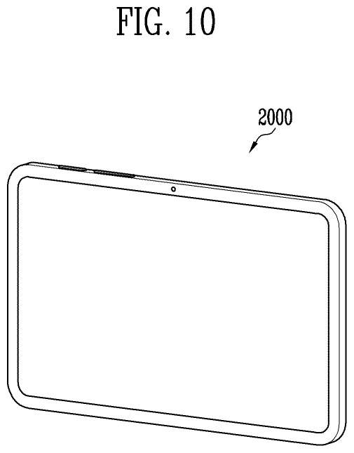

FIG. 9 is a block diagram illustrating an electronic device 2000 in accordance with embodiments of the present disclosure. FIG. 10 is a schematic diagram illustrating an example where the electronic device 2000 of FIG. 9 is a tablet computer.

Referring to FIGS. 9 to 10, the electronic device 2000 may include a processor 2010, a memory device 2020, a storage device 2030, an input/output (I/O) device 2040, a power supply 2050, and a display device 2060. The display device 2060 may be the display device of FIG. 1. The electronic device 2000 may further include various ports for communication with a video card, a sound card, a memory card, a USB device, or other systems. In an embodiment, as illustrated in FIG. 1, the electronic device 2000 may be implemented as a smartphone. In an embodiment, as illustrated in FIG. 10, the electronic device 2000 may be implemented as a table computer. However, the aforementioned examples are illustrative, and the electronic device 2000 is not limited to the aforementioned examples. For example, the electronic device 2000 may be implemented as a cellular phone, a video phone, a smart pad, a smartwatch, a navigation device for vehicles, a computer monitor, a laptop computer, a head-mounted display device, and so on.

The processor 2010 may perform specific calculations or tasks. In an embodiment, the processor 2010 may include at least one of a central processing unit, an application processor, a graphic processing unit, a communication processor, an image signal processor, a controller, or the like. The processor 2010 may be connected to other components through an address bus, a control bus, a data bus, and the like. In an embodiment, the processor 2010 may be connected to an expansion bus such as a peripheral component interconnect (PCI) bus. In an embodiment, the processor 2010 may provide input image data to the display device 2060. Hence, the display device 2060 may display an image based on the input image data provided from the processor 2010.

The memory device 2020 may store data needed to perform the operation of the electronic device 2000. The memory device 2020 may function as a working memory and/or a buffer memory for the processor 2010. For example, the memory device 2020 may include one or more volatile memory devices such as a dynamic random access memory (DRAM) device, a static random access memory (SRAM) device, and a mobile DRAM device.

The storage device 2030 may store data in response to control signals or data from the processor 2010. The storage device 2030 may include one or more non-volatile storages to retain the data even when the electronic device 2000 is powered off. In some embodiments, the storage device 2030 may include a solid state drive (SSD), a hard disk drive (HDD), a CD-ROM, or the like.

The I/O device 2040 may include input devices such as a keyboard, a keypad, a touchpad, a touch screen, and a mouse, and output devices such as a speaker and a printer. In an embodiment, the display device 2060 may be integrated with the I/O device 2040.

The power supply 2050 may supply power needed to perform the operation of the electronic device 2000. For example, the power supply 2050 may include a power management integrated circuit (PMIC). In an embodiment, the power supply 2050 may supply power to the display device 2060.

The display device 2060 may display images in response to image data signals and/or control signals from the processor 2010. The display device 2060 may be connected to other components through the buses or other communication links.

According to the embodiments of the present invention, a display device with improved driving reliability can be provided by inspecting conductivity in conductive areas of a display panel cover, a protective member, and a main printed circuit board.

Characteristics of embodiments according to the present disclosure are not limited by the above-described characteristics, and more various other characteristics are included in the embodiments according to the present disclosure.

What is claimed is:

1. An inspection system comprising:
a display device comprising:
a panel cover on a back surface of a display panel;
a printed circuit board on a back surface of the panel cover; and
a protective member on a front surface of the printed circuit board; and
an inspection device configured to determine conductivity between the panel cover, the printed circuit board, and the protective member based on a resistance measured from a first area of the protective member, a second area of the panel cover, and a third area of the printed circuit board.

2. The inspection system of claim 1, wherein the inspection device:
includes a first pin in contact with the first area, a second pin in contact with the second area, and a third pin in contact with the third area, and
simultaneously contacts the first to third pins to the first to third areas and determines the conductivity based on a measured resistance.

3. The inspection system of claim 2, wherein based on the first to third pins being simultaneously contacted to the first to third areas and the measured resistance being ‘0’, the inspection device is configured to determine that conductivity exists between the panel cover, the printed circuit board, and the protection member.

4. The inspection system of claim 1, wherein the protective member includes a conductive layer and a non-conductive layer, and
wherein the first area is an area where a portion of the non-conductive layer is removed and the conductive layer is exposed.

5. The inspection system of claim 4, wherein the conductive layer is on the front surface of the printed circuit board, and the non-conductive layer is on the conductive layer.

6. The inspection system of claim 4, wherein the second area is an area where a layer including a conductive material of the panel cover is exposed.

7. The inspection system of claim 6, wherein the second area is an area where a portion of a release paper protecting the panel cover is removed and the layer including the conductive material is exposed.

8. The inspection system of claim 6, wherein the printed circuit board includes a ground area, and
wherein the third area is an area where the protective member is removed and the ground area of the printed circuit board is exposed.

9. The inspection system of claim 8, wherein the ground area has a ground potential.

10. The inspection system of claim 2, wherein the inspection device includes an upper cover in contact with the first to third pins.

11. The inspection system of claim 2, wherein the inspection device includes a first wire connecting the first and second pins, a second wire connecting the second and third pins, and a third wire connecting the first and third pins.

12. The inspection system of claim 1, wherein the display panel further includes a bending area extending from the display panel, and
wherein the printed circuit board is positioned on a back surface of the panel cover as the bending area is bent.

13. An inspection device comprising:
a first pin in contact with a first area of a protective member of a display device;
a second pin in contact with a second area of a panel cover of the display device; and
a third pin in contact with a third area of a printed circuit board of the display device,
wherein conductivity between the panel cover, the printed circuit board, and the protective member is determined based on a resistance measured from the first to third areas.

14. The inspection device of claim 13, wherein the inspection device simultaneously contacts the first to third pins to the first to third areas and determines the conductivity based on a measured resistance.

15. The inspection device of claim 13, wherein based on the first to third pins being simultaneously contacted to the first to third areas and the measured resistance being ‘0’, the inspection device is configured to determine that conductivity exists between the panel cover, the printed circuit board, and the protection member.

16. The inspection device of claim 14, wherein the protective member includes a conductive layer and a non-conductive layer, and
wherein the first area is an area where a portion of the non-conductive layer is removed and the conductive layer is exposed.

17. The inspection device of claim 16, wherein the second area is an area where a layer including a conductive material of the panel cover is exposed.

18. The inspection device of claim 17, wherein the third area is an area where the protective member is removed and a ground area of the printed circuit board is exposed.

19. The inspection device of claim 13, further comprising:
an upper cover in contact with the first to third pins.

20. The inspection device of claim 13, wherein the panel cover is on a back surface of the display panel,
wherein the printed circuit board is on a back surface of the panel cover, and
wherein the protective member is on a front surface of the printed circuit board.

21. An electronic device, comprising:
a processor to provide input image data; and
a display device to display an image based on the input image data,
the display device comprising:
a panel cover on a back surface of a display panel;
a printed circuit board on a back surface of the panel cover; and
a protective member on a front surface of the printed circuit board; and
wherein conductivity between the panel cover, the printed circuit board, and the protective member is determined based on a resistance measured from a first area of the protective member, a second area of the panel cover, and a third area of the printed circuit board.

22. The electronic device of claim 21, wherein the protective member includes a conductive layer and a non-conductive layer, and
wherein the first area is an area where a portion of the non-conductive layer is removed and the conductive layer is exposed.

23. The electronic device of claim 21, wherein the display panel further includes a bending area extending from the display panel, and
wherein the printed circuit board is positioned on a back surface of the panel cover as the bending area is bent.
